(19) United States
(12) Patent Application Publication
(10) Pub. No.: US 2008/0105927 A1
(43) Pub. Date: May 8, 2008

(54) Memory devices and methods of manufacturing the same

(76) Inventors: Young-Joon Ahn, Yuseong-gu (KR); Jong-Jin Lee, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 11/711,117

(22) Filed: Feb. 27, 2007

(30) Foreign Application Priority Data
Nov. 6, 2006 (KR) 2006-108650

(51) Int. Cl. H01L 29/94; H01L 21/336

(52) U.S. Cl. 257/365; 438/283; 257/E21.409; 257/E29.345

(57) ABSTRACT

The memory device includes upper gate structures and lower gate structures formed on an active region of a substrate, and an insulation layer. Each of the upper gate structures may have a blocking layer pattern and a control gate electrode. Each of the lower gate structures may have a tunnel insulation layer pattern and a floating gate electrode. The floating gate electrode may include a lower portion that is narrower than an upper portion contacting with the upper gate structure. The insulation layer may cover gate structures formed of the lower and upper gate structures, and may include air gaps between adjacent gate structures.

### BACKGROUND OF THE INVENTION

1. Field of the Invention

The present invention is related to memory devices and methods of manufacturing the same. More particularly, the present invention is related to memory devices having a high coupling ratio, and methods of manufacturing the memory devices.

2. Description of the Related Art

Non-volatile memory devices include electrically erasable and programmable random access memory (EEPROM) devices, flash memory devices, etc. Flash memory devices may electrically control data input/output operations using Fowler-Nordheim (FN) tunneling or channel hot electron injection (CHEI). Generally, a cell transistor of flash memory devices may have a structure in which a tunnel insulation layer, a floating gate, a dielectric layer, and a control gate are sequentially stacked. Flash memory devices may be classified into NOR-type flash memory devices and NAND-type flash memory devices.

In NOR-type flash memory devices, electrical signals may be provided to source/drain regions of a unit cell transistor through pads, each of which may be electrically connected to each of the source/drain regions, respectively, thereby driving a unit cell. Since disposing the pads between the unit cell transistors requires space, achieving a high degree of integration in NOR-type flash memory devices may be difficult.

NAND-type flash memory devices may have a string structure in which a plurality of cell transistors is connected in series, and a string selection transistor and a ground selection transistor are connected to both ends of each of the cell transistors, respectively. Thus, input/output operations of NAND-type flash memory devices may be performed by the string, commonly including a 16 or 32 unit cell. In NAND-type flash memory devices, each of the pads may not necessarily be electrically connected to each of source/drain regions, respectively. Thus, NAND-type flash memory devices may advantageously allow a high degree of integration.

Generally, non-volatile memory devices may have a structure in which a floating gate for storing charges is inserted into a common metal-oxide-semiconductor (MOS) transistor. Particularly, the non-volatile memory devices may have a structure in which a tunnel insulation layer, a floating gate, a dielectric layer and a control gate are sequentially stacked on a semiconductor substrate. Data may be programmed in the non-volatile memory devices using, e.g., FN tunneling or CHEI.

When data is programmed in the non-volatile memory devices using FN tunneling, a high voltage may be applied to the control gate so that a high electric field may be applied to the tunnel insulation layer. Electrons in the semiconductor substrate may move into the floating gate through the tunnel insulation layer due to the high electric field.

When data is programmed in the non-volatile memory devices using CHEI, a high voltage may be applied to the control gate and a drain region, so that hot electrons generated in portions of the semiconductor substrate adjacent to the drain region may be injected into the floating gate through the tunnel insulation layer.

Thus, a high voltage must be applied to the tunnel insulation layer when data is programmed using either FN tunneling or CHEI. In order to apply the high voltage to the tunnel insulation layer, a high coupling ratio (C/R) is needed. The C/R may be represented by the following equation:

C/R=Cₒₙₒ/(Cₜᵤₙ+Cₒₙₒ)

Referring to the equation, Cₒₙₒ is a capacitance between the control gate and the floating gate, and Cₜᵤₙ is a capacitance of the tunnel insulation layer interposed between the floating gate and the semiconductor substrate. As shown in the equation, in order to increase the C/R, a first effective surface area of the floating gate overlapping the control gate may be increased and/or or a second effective surface area of the floating gate overlapping the tunnel insulation layer may be decreased. However, when the effective surface areas are increased, a non-volatile memory device having a high degree of integration may not be easily formed.

Recently, the control gate has been formed using a material having a high dielectric constant, i.e., a high-k material, in order to increase a capacitance of the non-volatile memory device. However, the high-k material may be more difficult to pattern than polysilicon included in the floating gate. Thus, forming a sidewall of the control gate to have a vertical profile may be difficult. Additionally, the floating gate may have a lower portion that is wider than an upper portion. Thus, the second effective surface area of the floating gate may be increased, thereby decreasing the C/R.

In the meantime, space between gate structures may decrease as integration of semiconductor devices has been increased. Generally, an insulation layer including an oxide may be formed between the gate structures in order to electrically insulate the gate structures therebetween. However, the oxide has a high dielectric constant, e.g., about 4, so that parasitic capacitances may be generated between the gate structures. Thus, an RC delay may occur in the non-volatile memory device.

As described above, it is not simple to simultaneously decrease the parasitic capacitances between the gate structures and increase the C/R. Thus, a non-volatile memory device having a high degree of integration, a decreased parasitic capacitance, and a desired C/R is still needed.

### SUMMARY OF THE INVENTION

The present invention is therefore directed to a memory device and method of manufacturing the same, which substantially overcome one or more of the problems due to the limitations and disadvantages of the related art.

It is a feature of an embodiment of the present invention to provide memory devices, and methods of manufacturing the same, having a high C/R.

It is another feature of an embodiment of the present invention to provide memory devices, and methods of manufacturing the same, having a decreased parasitic capacitance.

It is yet another feature of an embodiment of the present invention to provide memory devices, and methods of manufacturing the same, having a high degree of integration.

At least one of the above and other features and advantages of the present invention may by realized by providing a memory device including a plurality of upper gate structures, each upper gate structure including a blocking layer pattern and a control gate electrode, a plurality of lower gate structures on an active region of a semiconductor substrate, each lower gate structure including a tunnel insulation layer pattern and a floating gate electrode, wherein the floating gate electrode has a lower portion narrower than an upper portion, the lower portion contacts the tunnel insulation layer pattern, and the upper portion contacts the upper gate structure, and an insulation layer covering gate structures formed by the lower and upper gate structures.

Each of the upper gate structures may include a spacer formed on a sidewall of the control gate electrode. The spacer may include a medium temperature oxide (MTO). The spacer may extend downwardly from a sidewall of the control gate electrode to a sidewall of the blocking layer pattern.

A width of the floating gate electrode may decrease gradually from the upper portion to the lower portion.

The blocking layer pattern may include a high-k material having a dielectric constant higher than that of silicon nitride. The blocking layer pattern may include at least one of hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu).

The insulation layer includes an air gap between adjacent gate structures. The insulation layer may include silicon oxide.

At least one of the above and other features and advantages of the present invention may by realized by providing a method of manufacturing a memory device, the method including forming a plurality of upper gate structures, each upper gate structure includes a blocking layer pattern and a control gate electrode, forming a plurality of lower gate structures on an active region of a semiconductor substrate, each lower gate structure including a tunnel insulation layer pattern and a floating gate electrode, wherein the floating gate electrode has a lower portion that is narrower than an upper portion, the lower portion contacting the tunnel insulation layer pattern and the upper portion contacting the upper gate structure, and forming an insulation layer on the semiconductor substrate to cover gate structures formed by the lower and upper gate structures.

The method may include sequentially forming a tunnel insulation layer, a first conductive layer, a blocking layer and a second conductive layer on the active region of the semiconductor substrate.

Forming each of the upper gate structures may include forming a mask on the second conductive layer, forming the control gate electrode by patterning the second conductive layer using the mask as an etching mask, forming a spacer on a sidewall of the control gate, and forming the blocking layer pattern by patterning the blocking layer using the mask, the control gate electrode, and the spacer as etching masks. The method may further include forming a recess at a top surface of the conductive layer by partially removing the first conductive layer while patterning the blocking layer.

Forming each of the upper gate structures may include forming a mask on the second conductive layer, forming the control gate electrode and the blocking layer pattern by patterning the second conductive layer and the blocking layer using the mask as an etching mask, and forming a spacer on sidewalls of the control gate and the blocking layer pattern. The method may further include forming a recess at a top surface of the first conductive layer by an etching process using the spacer as an etching mask.

Forming the lower gate structure may include performing an isotropic etching process on the first conductive layer and the tunnel insulation layer. The spacer may be formed using a medium temperature oxide (MTO).

The insulation layer may include an air gap formed in a space between adjacent gate structures. The insulation layer is formed using silicon oxide by a PECVD process.

The blocking layer pattern may include a high-k material having a dielectric constant higher than that of silicon nitride.

### BRIEF DESCRIPTION OF THE DRAWINGS

The above and other features and advantages of the present invention will become more apparent to those of ordinary skill in the art by describing in detail example embodiments thereof with reference to the attached drawings, in which:

FIG. 1 illustrates a cross-sectional view of a memory device in accordance with a first embodiment of the present invention;

FIGS. 2 to 6 illustrate cross-sectional views of stages in a method of manufacturing the memory device in FIG. 1 in accordance with embodiments of the present invention;

FIG. 7 illustrates a cross-sectional view of a memory device in accordance with a second embodiment of the present invention; and

FIGS. 8 to 11 illustrate cross-sectional views of stages in a method of manufacturing the memory device in FIG. 7 in accordance with embodiments of the present invention.

### DETAILED DESCRIPTION OF THE INVENTION

Korean Patent Application No. 2006-108650 filed on Nov. 6, 2006, in the Korean Intellectual Property Office, and entitled: “Memory Devices and Methods of Manufacturing the Same,” is incorporated by reference herein in its entirety.

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

As will be described below in connection with embodiments of the present invention, a floating gate electrode may have a lower portion that is narrower than an upper gate structure, so that an effective surface area of the floating gate electrode overlapping the tunnel insulation layer pattern may be reduced. Thus, a capacitance of the tunnel insulation layer pattern may be decreased, while a C/R of the memory device may be increased. As a result, an operation voltage of the memory device while programming and erasing data may be reduced.

As will be described below in connection with embodiments of the present invention, the floating gate electrode may not necessarily have a large height in order to increase the C/R, so that disturbance due to parasitic capacitances by adjacent floating gate electrodes may be reduced. As a result, the memory device may have an increased window margin for data programming and erasing. Thus, the memory device may perform multi-level operations that may allow a plurality of data to be written into or read from one cell.

As will be described below in connection with embodiments of the present invention, an insulation layer including an air gap may have a low dielectric constant, e.g., about 1, thereby having a decreased total dielectric constant. Thus, generation of a parasitic capacitance may be reduced.

As will be described below in connection with embodiments of the present invention, a blocking layer pattern may have such a high dielectric constant that most voltages applied to the control gate may be transferred to the floating gate. Thus, the C/R may be increased and efficiency of data programming and erasing may be improved.

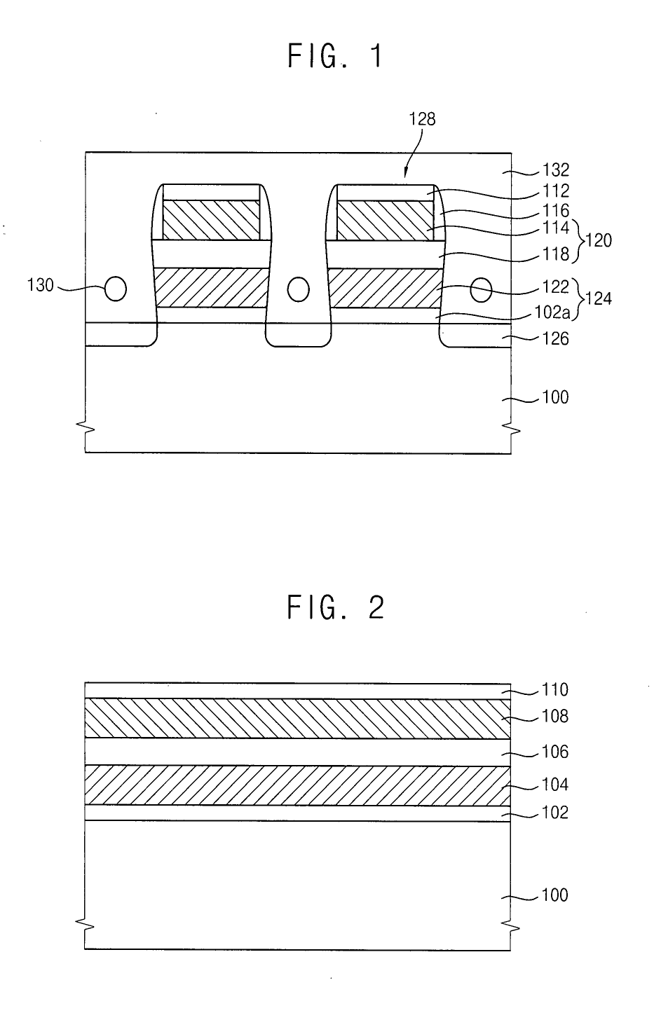

FIG. 1 illustrates a cross-sectional view of a memory device in accordance with a first embodiment of the present invention. Although FIG. 1 illustrates a NAND-type flash memory device, advantages of the present invention may be employed in a NOR-type flash memory device or in a volatile memory device, e.g., a dynamic random access memory (DRAM) device or a static random access memory (SRAM) device.

Referring to FIG. 1, a semiconductor substrate 100 on which a memory device is to be formed may be prepared. The semiconductor substrate 100 may include a silicon wafer.

An isolation layer (not shown) may be formed on the semiconductor substrate 100 to define an active region and a field region. The isolation layer may be formed by a shallow trench isolation (STI) process. Each of the active region and the field region may extend linearly in a first direction.

A gate structure 128 may include a lower gate structure 124 and an upper gate structure 120 that are sequentially stacked on the active region of the semiconductor substrate 100.

The lower gate structure 124 may include a tunnel insulation layer pattern 102a and a floating gate electrode 122 that are sequentially stacked. The floating gate electrode 122 may have a lower portion narrower than an upper portion.

The tunnel insulation layer pattern 102a may be formed, e.g., by a thermal oxidation process, on a surface of the semiconductor substrate 100. The floating gate electrode 122 may include polysilicon. The floating gate electrode 122 may have a width gradually decreasing downward and may be formed, e.g., by an anisotropic etching process, discussed below.

The floating gate electrode 122 having the lower portion narrower than the upper portion may have a reduced effective surface area that overlaps the tunnel insulation layer pattern 102a. Thus, a capacitance of the tunnel insulation layer pattern 102a may decrease, so that a C/R influencing programming and erasing characteristics of the memory device may be increased.

When the floating gate electrode 122 has a thickness of less than about 150 Å, a storage capacity may be decreased, and forming the floating gate electrode 122 by patterning the conductive layer 104 may become difficult. When the floating gate electrode 122 has a thickness of more than about 300 Å, a parasitic capacitance between adjacent floating gate electrodes 122 may be increased, thereby possibly generating disturbances between adjacent cells. When disturbances increase, a threshold voltage of a standard cell transistor may be changed due to data stored in adjacent cells. Therefore, the floating gate electrode 122 may have a thickness of about 150 Å to about 300 Å.

The upper gate structure 120 may include a blocking layer pattern 118 and a control gate electrode 114 that are sequentially stacked on the floating gate electrode 122. The blocking layer pattern 118 may include a high-k material, i.e., a material having a dielectric constant higher than that of a silicon nitride layer. For example, the blocking layer pattern 118 may include hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), etc.

When the blocking layer pattern 118 has a thickness of less than about 100 Å, a leakage current may be increased. When the blocking layer pattern 118 has a thickness of more than about 300 Å, a capacitance of the blocking layer pattern 118 may be decreased. Thus, the blocking layer pattern 118 may have a thickness of about 100 Å to about 300 Å.

The blocking layer pattern 118 may include a metal oxide having a high dielectric constant so that the capacitance of the blocking layer pattern 118 may be increased. Thus, the C/R influencing the programming and erasing characteristics of the memory device may be increased.

The control gate electrode 114 may be formed on the blocking layer pattern 118. The control gate electrode 114 may extend linearly in a second direction substantially perpendicular to the first direction.

The control gate electrode 114 may include polysilicon or a metal nitride. In an example embodiment of the present invention, the control gate electrode 114 may include a metal nitride having a high work function, e.g., about 4.6 to about 5.5 eV. Examples of the metal nitride include tantalum nitride, titanium nitride, etc. These may be used alone or in combination.

When the control gate electrode 114 includes the metal nitride having such a high work function, an energy barrier between the control gate electrode 114 and the blocking layer pattern 118 may be increased. Thus, reverse tunneling of charges from the control gate electrode 114 to the blocking layer pattern 118 may be decreased. The control gate electrode 114 may have a thickness of about 20 Å to about 1000 Å.

A spacer 116 may be formed on a sidewall of the control gate electrode 114 to protect the control gate electrode 114 during formation of the floating gate electrode 122. The control gate electrode 114 may be damaged when isotropic etching for forming the floating gate electrode 122 is performed. Thus, the spacer 116 may serve as a buffer layer for protecting the control gate electrode 114 while performing the isotropic etching. The spacer 116 may include a medium temperature oxide (MTO), which has a dielectric constant lower than that of the metal nitride included in the control gate electrode 114. Thus, the spacer 116 may reduce disturbance between adjacent cells.

A mask 112 for forming the upper gate structure 120 may be formed on the control gate electrode 114. The mask 112 may include a MTO. A source/drain region 126 may be formed at an upper portion of the semiconductor substrate 100 adjacent to the gate structure 128.

An insulation layer 132 may be formed on the semiconductor substrate 100 to sufficiently cover the gate structure 128. The insulation layer 132 may include an air gap 130 formed between the gate structures 128. Particularly, the insulation layer 132 may include an oxide, e.g., silicon oxide. The insulation layer 132 may be formed by a process having poor step coverage characteristics, e.g., a plasma-enhanced chemical vapor deposition (PECVD).

When the insulation layer 132 is formed, the oxide may move to spaces between the gate structures 128. However, spaces between the gate structures 128 may not be large enough, so the oxide may not readily fill the spaces. Thus, the insulation layer 132 having the air gap 130 may be easily formed. The insulation layer 132 including the air gap 130 may have a low dielectric constant, e.g., about 1 or less, thereby having a decreased total dielectric constant. Thus, generation of a parasitic capacitance may be reduced.

The memory device may include the blocking layer pattern 118 having the high dielectric constant and the floating gate electrode 122 having the reduced effective surface area that overlaps the tunnel insulation layer pattern 102a, thereby realizing a high C/R. The memory device may include the insulation layer 132 having the air gap 130 between the gate structures 128, so that disturbance due to parasitic capacitances by adjacent floating gate electrodes 122 may be reduced. As a result, the memory device may have an increased window margin for data programming and erasing. Thus, the memory device may perform multi-level operations that allow a plurality of data to be written into or read from one cell.

Hereinafter, a method of manufacturing the memory device in FIG. 1 in accordance with embodiments of the present invention will be illustrated.

FIGS. 2 to 6 illustrate cross-sectional views of stages in a method of manufacturing the memory device in FIG. 1 in accordance with embodiments of the present invention. Although FIGS. 2 to 6 illustrate a method of manufacturing the NAND-type flash memory device in FIG. 1, advantages of the present invention may be employed in a method of manufacturing a NOR-type flash memory device or a volatile memory device, e.g., a DRAM device or an SRAM device.

Referring to FIG. 2, an isolation layer (not shown) may be formed on the semiconductor substrate 100 to define an active region. For example, the isolation layer may be formed on the semiconductor substrate 100 by a local oxidation of silicon (LOCOS) process or a STI process.

A tunnel insulation layer 102, a first conductive layer 104, a blocking layer 106, a second conductive layer 108 and a mask layer 110 may be sequentially formed on the semiconductor substrate 100.

The tunnel insulation layer 102 may be formed using an oxide, e.g., silicon oxide. For example, the tunnel insulation layer 102 may be formed by thermally oxidizing the semiconductor substrate 100. The tunnel insulation layer 102 may be formed to have a thickness of about 30 Å to about 100 Å, e.g., about 40 Å.

The first conductive layer 104 may be formed using polysilicon. The first conductive layer 104 may be transformed into the floating gate electrode 122 for storing or releasing charges by a successive process. Thus, the first conductive layer 104 may be formed in consideration of a thickness of the floating gate electrode 122.

When the first conductive layer 104 is formed to have a thickness of less than about 150 Å, the first conductive layer 104 may have a poor capacity of storing charges, and may not be easily formed into the floating gate electrode 122 by patterning. When the first conductive layer 104 is formed to have a thickness of more than about 300 Å, parasitic capacitances between adjacent floating gate electrodes 122 may be increased. Thus, in an example embodiment of the present invention, the first conductive layer 104 may be formed to have a thickness of about 150 Å to about 300 Å.

The blocking layer 106 may electrically insulate the first conductive layer 104 from the second conductive layer 108. The blocking layer 106 may be formed using silicon oxide, silicon nitride, or a high-k material, i.e., a material having a dielectric constant higher than that of silicon nitride.

Examples of the high-k material may include hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), etc.

The blocking layer 106 may be formed of aluminum oxide or hafnium aluminum oxide, and may have a thickness of about 100 Å to about 400 Å. The blocking layer 106 may be formed by a chemical vapor deposition (CVD) process or an atomic layer deposition (ALD) process.

The second conductive layer 108 may be formed using polysilicon or a metal nitride. The second conductive layer 108 may be formed using a metal nitride, e.g., tantalum nitride or titanium nitride, which has a work function above about 4.5 eV and does not change the dielectric constant of the blocking layer 106.

When the second conductive layer 108 is formed using the metal nitride having such a high work function, an energy barrier between the second conductive layer 108 and the blocking layer 106 may be increased. Thus, reverse tunneling of charges from the control gate electrode 114 (see FIG. 1) to the blocking layer pattern 118 (see FIG. 1) may be reduced. The control gate electrode 114 may be formed from the second conductive layer 108, and the blocking layer pattern 118 may be formed from the blocking layer 106.

A polysilicon layer (not shown) may further be formed on the second conductive layer 108. The work function of the second conductive layer 108 may depend only on a layer, i.e., the metal nitride layer, making direct contact with the blocking layer 106. Thus, the polysilicon layer may not affect the work function of the second conductive layer 108. The polysilicon layer may assist in patterning the metal nitride layer and may protect the control gate electrode 114.

The mask layer 110 may be formed using a silicon nitride or a silicon oxide by a CVD process. When the mask layer 110 is formed using a material substantially the same as that used in successively forming the insulation layer 132 (see FIG. 1), the mask layer 110 may not be removed by an additional process. Otherwise, the mask layer 110 may be removed.

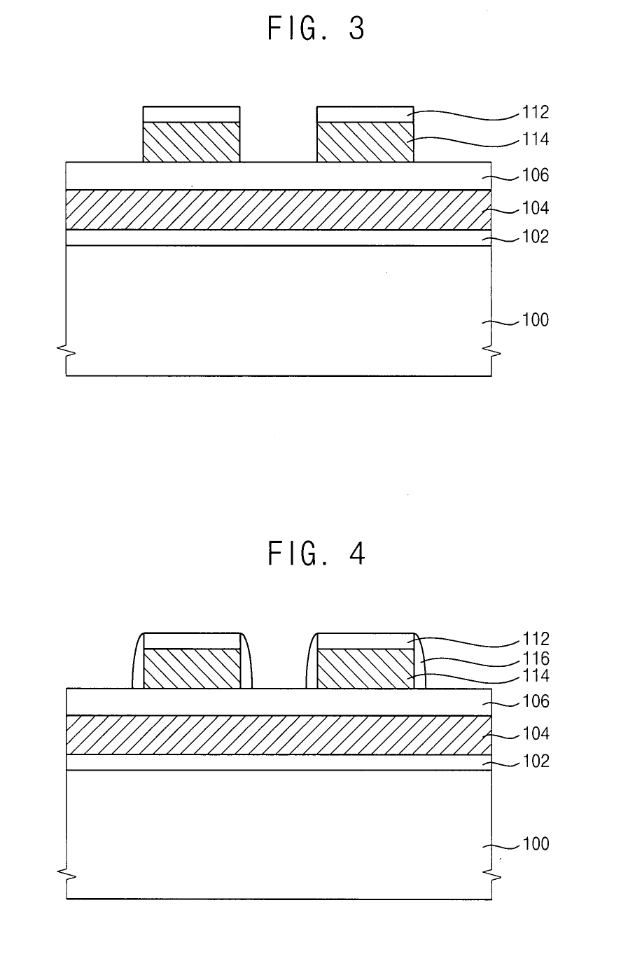

Referring to FIG. 3, the second conductive layer 108 may be patterned to form the control gate electrode 114.

Particularly, the mask layer 110 may be patterned using a photoresist pattern (not shown) to form a mask 112 by a photolithography process. The photoresist pattern may be removed by an ashing process and/or a stripping process. The second conductive layer 108 may be patterned using the mask 112 as an etching mask to form the control gate electrode 114.

Referring to FIG. 4, a spacer 116 may be formed on sidewalls of the control gate electrode 114 and the mask 112. For example, a plurality of the spacers 116 may be formed on the sidewalls of the control gate electrodes 114 and the masks 112.

The spacer 116 may protect the control gate electrode 114 during formation of the floating gate electrode 122. Particularly, an oxide layer (not shown) may be formed on the blocking layer 106 to cover the control gate electrode 114 and the mask 112. The oxide layer may be formed using a medium temperature oxide (MTO), which has a dielectric constant lower than that of a nitride layer, thereby reducing disturbance between adjacent memory cells.

The oxide layer may be formed using dichlorosilane gas and nitrous oxide gas by a low pressure chemical vapor deposition (LPCVD) process without performing a pre-treatment process on ammonia gas and nitrous oxide gas. Particularly, the oxide layer may be formed to have a single layer structure by simultaneously providing dichlorosilane gas and nitrous oxide gas at a flow rate ratio of about 1.0:1.7 to about 1.0:2.5.

The oxide layer may be partially removed, e.g., by anisotropic etching, to form the spacer 116 including the MTO on the sidewalls of the control gate electrode 114 and the mask 112.

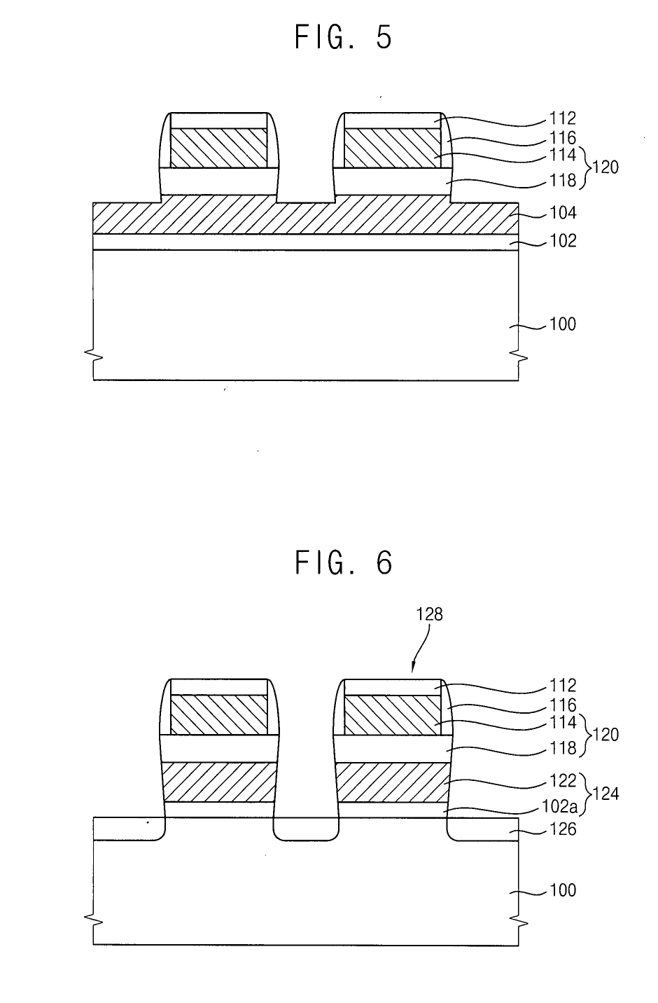

Referring to FIG. 5, the blocking layer 106 and the first conductive layer 104 may be partially removed.

Particularly, the blocking layer 106 may be patterned by an etching process, using the mask 112, the control gate electrode 114, and the spacer 116 as etching masks, to form the blocking layer pattern 118 on the first conductive layer 104. While patterning the blocking layer 106, a top surface of the first conductive layer 104 may also be etched to form a recess.

The recess may be formed to have a depth of about 10 Å to about 20 Å. The recess may prevent the blocking layer 106 from being damaged by excessive etching while forming the floating gate electrode 122.

Forming the floating gate electrode 122 having a desired shape by an isotropic etching process is not easy, because the blocking layer pattern 118 may inadvertently be removed while patterning the first conductive layer 104 by the isotropic etching process. Thus, by previously forming the recess at the top surface of the first conductive layer 104, the floating gate electrode 122 may be formed, while reducing or eliminating removal of the blocking layer pattern 118.

The upper gate structure 120 including the blocking layer pattern 118 and the control gate electrode 114 that are sequentially stacked on the floating gate electrode 122 and the spacer 116 may be formed by the above-described processes.

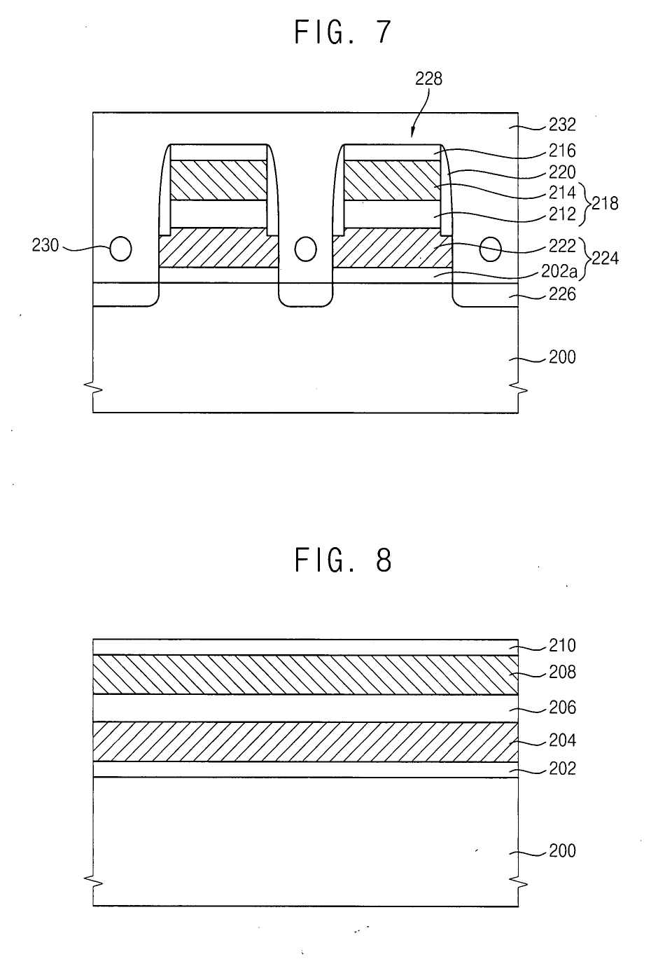

Referring to FIG. 6, the lower gate structure 124, including the tunnel insulation layer pattern 102a and the floating gate electrode 122 that are sequentially stacked on the semiconductor substrate 100, may be formed. The floating gate electrode 122 may have a lower portion that is narrower than the upper gate structure 120.

Particularly, the first conductive layer 104 may be partially etched by an isotropic etching process, e.g., a chemical dry etching process, to form the floating gate electrode 122. The floating gate electrode 122 may be formed to have the lower portion be narrower than the upper gate structure 120. Additionally, the tunnel insulation layer 102 may be partially etched by the isotropic etching process or another etching process to form the tunnel insulation layer pattern 102a. Thus, the lower gate structure 124, including the tunnel insulation layer pattern 102a and the floating gate electrode 122, which has the lower portion narrower than the upper gate structure 120, sequentially stacked on the semiconductor substrate 100, may be formed.

Before performing the isotropic etching process, the first conductive layer 104 may be further partially removed by an etching process to further deepen the recess. By further deepening the recess at the top surface of the first conductive layer 104, possible removal of the blocking layer pattern 118 may be further reduced or eliminated during formation of the floating gate electrode 122.

Impurities may be implanted onto the semiconductor substrate 100, using the lower gate structure 124 and the upper gate structure 120 as ion implantation masks, to form source/drain region 126 at a top surface of the semiconductor substrate 100 adjacent to the lower gate structure 124.

Referring again to FIG. 1, the insulation layer 132 having the air gap 126 may be formed on the semiconductor substrate 100 to sufficiently cover the gate structure 128. Particularly, the insulation layer 132 may be formed by a process having poor step coverage characteristics, e.g., a PECVD process, using an oxide, e.g., silicon oxide, so that the oxide may not completely fill spaces between the gate structures 128.

While the insulation layer 132 is formed, the oxide may move to the spaces between the gate structures 128. However, the spaces between the gate structures 128 may not be large enough, so the oxide may not fill the spaces. Thus, the insulation layer 132 having the air gap 130 may be easily formed.

The insulation layer 132 including the air gap 130 may have a low dielectric constant, e.g., about 1 or less, thereby having a decreased total dielectric constant. Thus, generation of a parasitic capacitance may be reduced.

The floating gate electrode 122 may have the lower portion narrower than the upper gate structure 120 so that the effective surface area of the floating gate electrode 122 overlapped with the tunnel insulation layer pattern 102a may be reduced. Thus, a capacitance of the tunnel insulation layer pattern 102a may be decreased. Additionally, the memory device includes the blocking layer pattern 118 having a high dielectric constant so that a capacitance of the blocking layer pattern 118 may be increased. As a result, a C/R of the memory device may be increased. As a result, an operation voltage of the memory device while programming and erasing data may be reduced.

FIG. 7 illustrates a cross-sectional view of a memory device in accordance with a second embodiment of the present invention. The memory device in FIG. 7 is the same as or similar to the memory device in FIG. 1, except that a spacer may extend downward from a sidewall of a control gate electrode to a sidewall of a blocking layer pattern.

Referring to FIG. 7, a lower gate structure 224 may include a tunnel insulation layer pattern 202a and a floating gate electrode 222 that are sequentially stacked on an active region of a semiconductor substrate 200, which may be defined by an isolation layer (not shown). An upper gate structure 218 may include a blocking layer pattern 212 and a control gate electrode 214 that are sequentially stacked on the lower gate structure 224.

The floating gate electrode 222 may be formed by an anisotropic etching process on a third conductive layer 204 (see FIG. 8) to have a width that gradually decreases downward, e.g., from an upper portion to a lower portion thereof. The floating gate electrode 222 having the lower portion narrower than the upper portion may have a reduced effective surface area that overlaps the tunnel insulation layer pattern 202a. Thus, a capacitance of the tunnel insulation layer pattern 202a decreases so that a C/R, which may influence programming and erasing characteristics of the memory device, may be increased.

The upper gate structure 218 may include a blocking layer pattern 212 and a control gate electrode 214 that are sequentially stacked on the floating gate electrode 222. The blocking layer pattern 212 may include a high-k material, e.g., a metal oxide, so that a capacitance of the blocking layer pattern 212 and the C/R may be increased.

A spacer 220 may be formed on sidewalls of the control gate electrode 214 and the blocking layer pattern 212 to protect the control gate electrode 214 and the blocking layer pattern 212 during formation of the floating gate electrode 222.

A mask 216 for forming the upper gate structure 218 may be formed on the control gate electrode 214. Source/drain region 226 may be formed at an upper portion of the semiconductor substrate 200 adjacent to the gate structure 228.

An insulation layer 232 may be formed on the semiconductor substrate 100 to sufficiently cover the gate structure 228. The insulation layer 232 may include an air gap 230 formed between the gate structures 228. Particularly, the insulation layer 232 may include an oxide, e.g., silicon oxide. The insulation layer 232 may be formed by a process having poor step coverage characteristics, e.g., a PECVD process.

While the insulation layer 232 is formed, the oxide may fill spaces between the gate structures 228. However, the spaces between the gate structures 228 may not be large enough, so the oxide may not completely fill the spaces. Thus, the insulation layer 232 having the air gap 230 may be easily formed. The insulation layer 232 including the air gap 230 may have a low dielectric constant, e.g., about 1 or less, thereby having a decreased total dielectric constant. Thus, generation of a parasitic capacitance may be reduced.

The memory device in accordance with the second embodiment of the present invention may include the blocking layer pattern 212 having the high dielectric constant and the floating gate electrode 222 having the reduced effective surface area that overlaps the tunnel insulation layer pattern 202a, thereby having a high C/R. The memory device in accordance with the second embodiment may include the insulation layer 232 having the air gap 230 between the gate structures 228, so that disturbance due to parasitic capacitances by adjacent floating gate electrodes 222 may be reduced.

Hereinafter, a method of manufacturing the memory device in FIG. 7 in accordance with embodiments of the present invention will be illustrated. FIGS. 8 to 11 illustrate cross-sectional views of stages in a method of manufacturing the memory device in FIG. 7 in accordance with embodiments of the present invention.

Referring to FIG. 8, an isolation layer (not shown) may be formed on the semiconductor substrate 200 to define an active region. Particularly, the isolation layer may be formed on the semiconductor substrate 200 by a LOCOS process or a STI process.

A tunnel insulation layer 202, a third conductive layer 204, a blocking layer 206, a fourth conductive layer 208 and a mask layer 210 may be sequentially formed on the semiconductor substrate 200.

The tunnel insulation layer 202 may be formed using an oxide, e.g., silicon oxide. The tunnel insulation layer 202 may be formed by thermally oxidizing the semiconductor substrate 200. The third conductive layer 204 may be formed using polysilicon. The blocking layer 206 may electrically insulate the third conductive layer 204 from the fourth conductive layer 208. The blocking layer 206 may be formed using silicon oxide, silicon nitride, or a high-k material, i.e., a material having a dielectric constant higher than that of silicon nitride.

The fourth conductive layer 208 may be formed using polysilicon or a metal nitride. When the fourth conductive layer 208 is formed using the metal nitride having a high work function, an energy barrier between the fourth conductive layer 208 and the blocking layer 206 may be larger. Thus, reverse tunneling of charges from the control gate electrode 214 to the blocking layer pattern 212 may be reduced (see FIG. 7). The control gate electrode may be formed from the fourth conductive layer 208, and the blocking layer pattern 212 may be formed from the blocking layer 206.

The mask layer 210 may be formed using a silicon nitride or a silicon oxide by a CVD process. When the mask layer 210 is formed using a material substantially the same as that used in successively forming the insulation layer 232 (see FIG. 7), the mask layer 210 may not be removed by an additional process. Otherwise, the mask layer 210 may be removed.

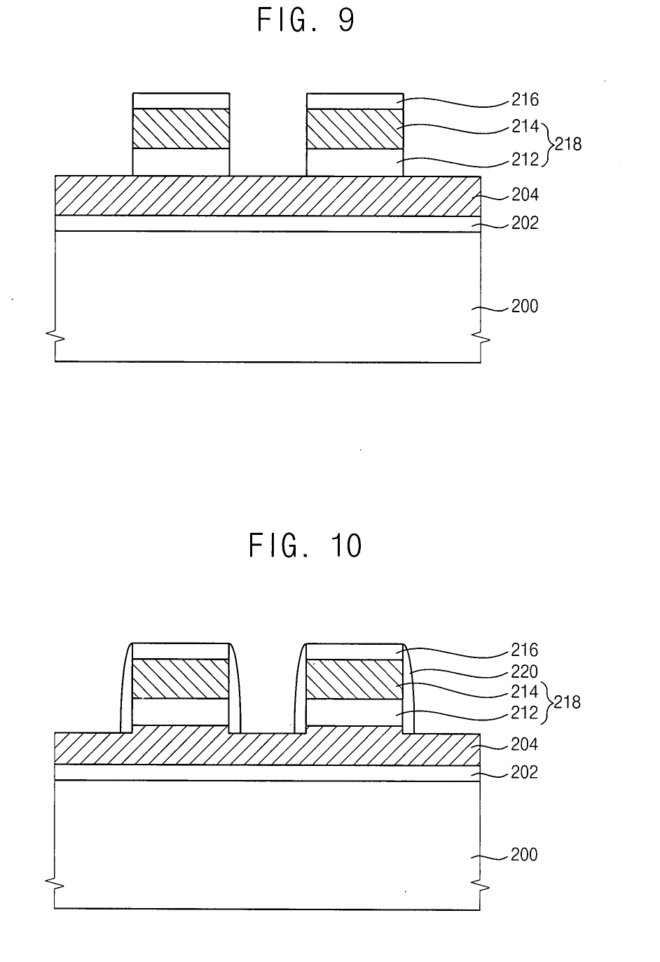

Referring to FIG. 9, the fourth conductive layer 208 and the blocking layer 206 may be patterned to form the upper gate structure 218 including the blocking layer pattern 212 and the control gate electrode 214 that are sequentially stacked on the third conductive layer 204.

Particularly, the mask layer 210 may be patterned using a photoresist pattern (not shown) by a photolithography process to form a mask 216. The photoresist pattern may be removed, e.g., by an ashing process and/or a stripping process. The fourth conductive layer 208 and the blocking layer 206 may be patterned using the mask 216 as an etching mask to form the upper gate structure 218.

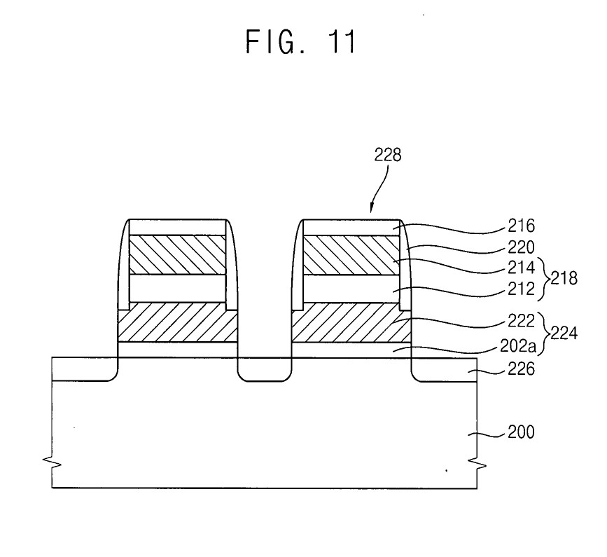

Referring to FIG. 10, the spacer 220 may be formed on sidewalls of the blocking layer pattern 212, the control gate electrode 214 and the mask 216. For example, a plurality the spacers 220 may be formed on the sidewalls of the blocking layer patterns 212, the control gate electrodes 214, and the masks 216. The spacer 220 may protect the blocking layer pattern 212 and the control gate electrode 214 during formation of the floating gate electrode 222.

Particularly, the third conductive layer 204 may be partially removed, e.g., by an etch back process, a chemical mechanical polishing (CMP) process, or a combination process thereof, to form a recess. The recess may be formed to have a depth of about 10 Å to about 20 Å. The recess may prevent the blocking layer pattern 212 from being damaged by excessive etching during formation of the floating gate electrode 222.

An oxide layer (not shown) may be formed using an oxide, e.g., MTO, on the third conductive layer 204 to cover the blocking layer pattern 212, the control gate electrode 214, and the mask 216. The oxide layer may be partially removed by an anisotropic etching process to form the spacer 220 on the sidewalls of the blocking layer pattern 212, the control gate electrode 214, and the mask 216.

Referring to FIG. 11, the lower gate structure 224, including the tunnel insulation layer pattern 202a and the floating gate electrode 222 that are sequentially stacked on the semiconductor substrate 200, may be formed. The floating gate electrode 222 may have a lower portion that is narrower than the upper gate structure 218.

Particularly, the third conductive layer 204 may be partially etched by an isotropic etching process, e.g., a chemical dry etching process, to form the floating gate electrode 222. The floating gate electrode 222 may be formed to have the lower portion narrower than the upper gate structure 218. Additionally, the tunnel insulation layer 202 may be partially etched by the isotropic etching process or another etching process to form the tunnel insulation layer pattern 202a. Thus, the lower gate structure 224, including the tunnel insulation layer pattern 202a and the floating gate electrode 222 that are sequentially stacked on the semiconductor substrate 200, may be formed. The lower portion of the floating gate electrode 222 may be narrower then the upper gate structure 218.

Before performing the isotropic etching process, the third conductive layer 204 may be further partially removed by an etching process to deepen the recess.

Impurities may be implanted onto the semiconductor substrate 200, using the lower gate structure 224 and the upper gate structure 218 as ion implantation masks, to form source/drain region 226 at a top surface of the semiconductor substrate 200 adjacent to the lower gate structure 218.

The floating gate electrode 222 may have the lower portion narrower than the upper gate structure 218, so that an effective surface area of the floating gate electrode 222 overlapping the tunnel insulation layer pattern 202a may be reduced. Thus, a capacitance of the tunnel insulation layer pattern 202a may be decreased.

Referring again to FIG. 7, the insulation layer 232 having the air gap 226 may be formed on the semiconductor substrate 200 to sufficiently cover the gate structure 228. Particularly, the insulation layer 232 may be formed by a process having poor step coverage characteristics, e.g., a PECVD process, using an oxide, e.g., silicon oxide, so that the oxide may not completely fill spaces between the gate structures 228.

The insulation layer 232 including the air gap 230 may have a low dielectric constant, e.g., about 1 or less, thereby having a decreased total dielectric constant. Thus, generation of a parasitic capacitance may be reduced.

The floating gate electrode 222 may have the lower portion narrower than the upper gate structure 218 so that the effective surface area of the floating gate electrode 222 overlapping the tunnel insulation layer pattern 202a may be reduced. Thus, a capacitance of the tunnel insulation layer pattern 202a may be decreased. The memory device may include the blocking layer pattern 212 having a high dielectric constant so that a capacitance of the blocking layer pattern 212 may be increased. Furthermore, the insulation layer 232 may include the air gap 230 having the low dielectric constant of about 1, thereby having a decreased total dielectric constant. Thus, generation of the parasitic capacitance may be reduced.

According to some embodiments of the present invention, the memory device may include a floating gate electrode having a reduced effective surface area that overlaps a tunnel insulation layer pattern, thereby increasing C/R. According to some embodiments of the present invention, the memory device may include a blocking layer pattern having a high dielectric constant, so that a capacitance of the blocking layer pattern may be increased, thereby increasing C/R. According to some embodiments of the present invention, the memory device may include an insulation layer having an air gap between gate structures so that disturbance due to parasitic capacitances by adjacent floating gate electrodes may be reduced. As a result, an operation voltage of the memory device while programming and erasing data may be reduced, and the memory device may have an increased window margin for data programming and erasing, thereby allowing a high degree of integration.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A memory device, comprising:
a plurality of upper gate structures, each upper gate structure including a blocking layer pattern and a control gate electrode;
a plurality of lower gate structures on an active region of a semiconductor substrate, each lower gate structure including a tunnel insulation layer pattern and a floating gate electrode, wherein the floating gate electrode has a lower portion narrower than an upper portion, the lower portion contacts the tunnel insulation layer pattern and the upper portion contacts the upper gate structure; and
an insulation layer configured to cover gate structures including the lower and upper gate structures.

2. The memory device as claimed in claim 1, wherein each of the upper gate structures includes a spacer formed on a sidewall of the control gate electrode.

3. The memory device as claimed in claim 2, wherein the spacer includes a medium temperature oxide (MTO).

4. The memory device as claimed in claim 2, wherein the spacer extends downwardly from the sidewall of the control gate electrode to a sidewall of the blocking layer pattern.

5. The memory device as claimed in claim 1, wherein a width of the floating gate electrode decreases gradually from the upper portion to the lower portion.

6. The memory device as claimed in claim 1, wherein the blocking layer pattern includes a high-k material having a dielectric constant higher than that of silicon nitride.

7. The memory device as claimed in claim 6, wherein the blocking layer pattern comprises at least one of hafnium (Hf), zirconium (Zr), tantalum (Ta), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu).

8. The memory device as claimed in claim 1, wherein the insulation layer includes an air gap between adjacent gate structures.

9. The memory device as claimed in claim 8, wherein the insulation layer includes silicon oxide.

10. A method of manufacturing a memory device, the method comprising:
forming a plurality of upper gate structures, each upper gate structure includes a blocking layer pattern and a control gate electrode;
forming a plurality of lower gate structures on an active region of a semiconductor substrate, each lower gate structure including a tunnel insulation layer pattern and a floating gate electrode, wherein the floating gate electrode has a lower portion that is narrower than an upper portion, the lower portion contacting the tunnel insulation layer pattern and the upper portion contacting the upper gate structure; and
forming an insulation layer on the semiconductor substrate to cover gate structures including the lower and upper gate structures.

11. The method as claimed in claim 10, further comprising sequentially forming a tunnel insulation layer, a first conductive layer, a blocking layer and a second conductive layer on the active region of the semiconductor substrate.

12. The method as claimed in claim 11, wherein forming each of the upper gate structures comprises:
forming a mask on the second conductive layer;
forming the control gate electrode by patterning the second conductive layer using the mask as an etching mask;
forming a spacer on a sidewall of the control gate; and
forming the blocking layer pattern by patterning the blocking layer using the mask, the control gate electrode, and the spacer as etching masks.

13. The method as claimed in claim 12, wherein the spacer is formed using a medium temperature oxide (MTO).

14. The method as claimed in claim 12, further comprising forming a recess at a top surface of the conductive layer by partially removing the first conductive layer while patterning the blocking layer.

15. The method as claimed in claim 11, wherein forming each of the upper gate structures comprises:
forming a mask on the second conductive layer;
forming the control gate electrode and the blocking layer pattern by patterning the second conductive layer and the blocking layer using the mask as an etching mask; and
forming a spacer on sidewalls of the control gate and the blocking layer pattern.

16. The method as claimed in claim 15, further comprising forming a recess at a top surface of the first conductive layer by an etching process using the spacer as an etching mask.

17. The method as claimed in claim 11, wherein forming the lower gate structure comprises performing an isotropic etching process on the first conductive layer and the tunnel insulation layer.

18. The method as claimed in claim 10, wherein the insulation layer includes an air gap formed in a space between adjacent gate structures.

19. The method as claimed in claim 18, wherein the insulation layer is formed using silicon oxide by a PECVD process.

20. The method as claimed in claim 10, wherein the blocking layer pattern includes a high-k material having a dielectric constant higher than that of silicon nitride.
